(19) United States
(12) Patent Application Publication
(10) Pub. No.: US 2018/0130728 A1
(43) Pub. Date: May 10, 2018

(54) SILICON SUBSTRATE PROCESSING METHOD, ELEMENT EMBEDDED SUBSTRATE, AND CHANNEL FORMING SUBSTRATE

(71) Applicant: SEIKO EPSON CORPORATION, Tokyo (JP)

(72) Inventor: Kazuhiro GOMI, Chino-shi (JP)

(73) Assignee: SEIKO EPSON CORPORATION, Tokyo (JP)

(21) Appl. No.: 15/791,152

(22) Filed: Oct. 23, 2017

Related U.S. Application Data
(62) Division of application No. 14/174,235, filed on Feb. 6, 2014, now abandoned.

(30) Foreign Application Priority Data
Feb. 6, 2013 (JP) 2013-021119

(51) Int. Cl. H01L 23/498; H01L 21/768; B41J 2/16; B81C 1/00; H01L 21/268; H01L 21/306

(52) U.S. Cl. CPC H01L 23/49827; H01L 21/76898; B81C 2201/0143; B41J 2/1645; B41J 2/1634; B41J 2/1629; H01L 2924/00; B41J 2/161; B81C 1/00087; H01L 21/268; H01L 2924/0002; H01L 21/30604; H01L 21/306; B41J 2/1628

(57) ABSTRACT

A silicon substrate processing method includes forming an etching mask which has an opening portion, on a surface of a silicon substrate, forming an etching guide hole in the opening portion on the silicon substrate, and forming a through-hole which passes through the silicon substrate, by applying an etching treatment onto the silicon substrate in which the etching guide hole is formed. In the forming of the guide hole, the etching guide hole passing through the silicon substrate is formed by irradiating the opening portion with a laser beam a plurality of times, with a cooling period between each instance of irradiation with the laser beam.

### BACKGROUND

### 1. Technical Field

The present invention relates to a silicon substrate processing method, an element embedded substrate, and a channel forming substrate.

### 2. Related Art

A micromachine having an ultra-small movable mechanism has been examined in terms of a micromechanics technology. Particularly, a microstructure which is formed in a single crystal silicon substrate using a semiconductor integrated circuit forming technology (a semiconductor photolithography process) allows a plurality of minute mechanical parts having a small size and high manufacturer reproducibility to be formed in the substrate. In the micromechanics technology using the semiconductor photolithography process, Bulk Micro-Machining in which silicon crystal axis anisotropic etching using an etching rate difference between a silicon surface (111) and other crystal surfaces is performed has been known. The Bulk Micro-Machining is an essential technology for precisely forming a through-hole which is used for forming a thin-film cantilever, a nozzle, or the like.

In recent years, a micromachine having a finer structure and high precision has been required, and thus it is necessary to densely form through-holes having smaller diameters. A method in which minute perforations are formed in advance in opening portions of the through-holes to be finally obtained, and then the through-holes having small diameters are densely formed using the minute perforations as etching guide holes has been proposed as a technology for precisely forming through-holes (see JP-A-5-309835).

However, in the technology described above, the etching guide hole (the minute perforation) is formed by a drilling process using a laser beam. Furthermore, when the perforations are formed in the silicon substrate, a silicon in the vicinity of the perforations is thermally reformed at the same time. During the etching guide hole forming, heat quantity owing to irradiation with a laser beam is large in the opening portion, that is, in the vicinity of an incident surface, and thus thermal reforming is likely to progress to the deeper layer. Particularly, in a case where an aspect ratio is large, it is necessary to increase laser-beam energy or extend irradiation time. Thus, the influence is significant. The thermal reformed portion is easily removed by etching. Therefore, in the through-hole obtained by the etching, the diameter of the opening portion is relatively larger than the diameter of the other portion. Accordingly, it is difficult to form the through-holes having small diameters, and thus the density of the through-holes is limitingly increased.

### SUMMARY

An advantage of some aspects of the invention is to solve at least a part of the problems described above, and the invention can be implemented as the following forms or application examples.

### Application Example 1

This application example is directed to a silicon substrate processing method including: forming an etching mask which has an opening portion on a surface of a silicon substrate; forming an etching guide hole in the opening portion on the silicon substrate; and forming a through-hole which passes through the silicon substrate, by applying an etching treatment onto the silicon substrate in which the etching guide hole is formed, in which, in the forming of the etching guide hole, the etching guide hole passing through the silicon substrate is formed by irradiating the opening portion with a laser beam a plurality of times, with a cooling period between each instance of irradiation with the laser beam.

According to this method, to form the etching guide hole, laser-beam irradiation is performed a plurality of separate times from the same direction. The silicon substrate is melted and evaporated by heat of the applied laser beam, and thus the perforation is formed in a laser-beam irradiation direction. Precedent laser-beam irradiation is performed, that is, one perforation is formed, and then subsequent laser-beam irradiation is performed after the cooling period. Therefore, an inner surface of the perforation, which includes an entrance portion of the precedently-formed perforation, is stabilized. Accordingly, in the subsequent laser-beam irradiation, it is easy for the laser beam to be multiply reflected and advance to the deep portion of the perforation. As a result, it is possible to form a new perforation of which a starting point is in the vicinity of the bottom portion of the precedently-formed perforation, while suppressing the entrance portion of the precedently-formed perforation from increasing in diameter and suppressing the thermal reforming from progressing. This operation is performed repeatedly, and thus it is possible to form the etching guide hole which passes through the silicon substrate, while suppressing the entrance portion thereof from increasing in diameter and suppressing the thermal reforming from excessively progressing.

Furthermore, in the through-hole forming, the etching guide hole and the thermal reformed portion surrounding the etching guide hole are subjected to etching treatment, and thus the through-hole is formed. The entrance portion of the etching guide portion is suppressed from increasing in diameter, and the thermal reforming of the etching guide hole is suppressed from excessively progressing. Thus, it is possible to suppress the through-hole from increasing in bore diameter. As a result, it is possible to densely arrange the through-holes having minute diameters on the silicon substrate.

### Application Example 2

This application example is directed to the silicon substrate processing method according to the application example described above, wherein in the forming of the guide hole, irradiation energy of the subsequently-applied laser beam is greater than the irradiation energy of the precedently-applied laser beam.

According to this method, it is easy to form a new perforation of which a starting point is in the vicinity of the bottom portion of the precedently-formed perforation.

### Application Example 3

This application example is directed to a silicon substrate processing method including: forming an etching mask which has opening portions, on a surface of a silicon substrate; forming an etching guide hole in each opening portion on the silicon substrate; and forming a through-hole which passes through the silicon substrate, by applying an etching treatment onto the silicon substrate on which the etching guide hole is formed, in which, in the forming of the etching guide hole, non-through-holes are respectively formed in the opening portions by irradiating the opening portions with a laser beam from two opposing surfaces of the silicon substrate.

According to this method, the laser-beam irradiation to form the etching guide holes is performed on the front and back surfaces of silicon substrate. Thus, it is possible to suppress the entrance portion from increasing in diameter and suppress thermal reforming from excessively progressing, both of which are caused by a concentration of the laser-beam energy on the entrance portion of either one of the etching guide holes (the perforations). As a result, it is possible to form the etching guide hole in which the diameter of the entrance portion is suppressed from increasing and the thermal reforming is suppressed from excessively progressing.

Furthermore, in the through-hole forming process, the etching guide hole and the thermal reformed portion surrounding the etching guide hole are subjected to etching treatment, and thus the through-hole is formed. The entrance portion of the etching guide portion is suppressed from increasing in diameter, and the thermal reforming of the etching guide hole is suppressed from excessively progressing. Thus, it is possible to suppress the through-hole from increasing in bore diameter. As a result, it is possible to densely arrange the through-holes having minute diameters on the silicon substrate.

### Application Example 4

This application example is directed to the silicon substrate processing method according to the application example described above, wherein two non-through-holes formed in the forming of the guide hole have portions overlapping in the thickness of the silicon substrate.

According to this method, in non-through-holes (the perforations) which are formed by irradiating the front and back surfaces of the silicon substrate with a laser beam, hollow portions or thermal reformed portions have portions overlapping in the thickness of the silicon substrate. Thus, it is possible to perform the etching treatment on two non-through-holes which have overlap portions and are used as an etching guide hole.

### Application Example 5

This application example is directed to a silicon substrate processing method including: forming an etching mask which has an opening portion, on a surface of a silicon substrate; forming a laser-beam irradiated portion which has an island shape around which a gap is provided when seen in a plan view, in the opening portion on the silicon substrate; forming an etching guide hole which passes through the silicon substrate, by irradiating the laser-beam irradiated portion on the silicon substrate with a laser beam; and forming a through-hole which passes through the silicon substrate, by applying an etching treatment onto the silicon substrate on which the etching guide hole is formed.

According to this method, the laser-beam irradiated portion having an island shape around which a groove (the gap) is provided is formed at a position to be irradiated with a laser beam. Thus, even when the laser-beam irradiated portion is irradiated with a laser beam to form the etching guide hole, thermal energy of the laser beam is blocked by the gap, and thus it is difficult for thermal energy to be transmitted in a radial direction of the etching guide hole. As a result, it is possible to form the etching guide hole passing through the silicon substrate while suppressing the entrance portion from increasing in diameter and suppressing thermal reforming of the entrance portion from excessively progressing, both of which are caused by a concentration of the thermal energy of the laser beam on the entrance portion of the etching guide holes.

Furthermore, in the through-hole forming process, the etching guide hole and the thermal reformed portion surrounding the etching guide hole are subjected to etching treatment, and thus the through-hole is formed. The entrance portion of the etching guide portion is suppressed from increasing in diameter, and the thermal reforming of the etching guide hole is suppressed from excessively progressing. Thus, it is possible to suppress the through-hole from increasing in bore diameter. As a result, it is possible to densely arrange the through-holes having minute diameters on the silicon substrate.

### Application Example 6

This application example is directed to the silicon substrate processing method according to the application example described above, wherein in the forming of the laser-beam irradiated portion, the laser-beam irradiated portion is formed by applying an etching treatment onto the silicon substrate.

According to this method, the laser-beam irradiated portion having an island shape around which the groove (the gap) having a predetermined depth is provided is formed at a position at which an opening portion is to be formed, on the silicon substrate.

### Application Example 7

This application example is directed to an element embedded substrate including: a silicon substrate on which a through-hole is formed by the silicon substrate processing methods described above; a first insulation layer that is formed over one surface of the silicon substrate and an inner surface of the through-hole; a conductor that is surrounded by the first insulation layer and provided in the through-hole; a wiring layer that is connected to the conductor and provided on the one surface of the silicon substrate via the first insulation layer; and an element circuit that is electrically connected to the wiring layer.

According to this method, the element embedded substrate has a through electrode formed using the through-hole which has a minute diameter and is densely arranged in the silicon substrate. Thus, it is possible to provide a compact element embedded substrate capable of realizing fine and high-density mounting.

### Application Example 8

This application example is directed to a channel forming substrate, which is applied to liquid discharge head for discharging functional liquid as droplets, including: a nozzle plate on which, at least, nozzles through which the droplets are discharged are formed; a cavity forming substrate of which one surface is connected to one surface of the nozzle plate to form a cavity to accumulate the functional liquid; a diaphragm that is connected to the other surface of the cavity forming substrate and is displaced by driving of a driving element; and a reservoir forming substrate that is connected to a surface of the diaphragm, which is opposite the surface connected to the cavity forming substrate, to form a reservoir, in which parts of the plurality of channels through which the functional liquid passes are through-holes formed by the silicon substrate processing methods described above.

According to this configuration, in the channel forming substrate, the through-holes which have minute diameters and are densely arranged in the silicon substrate can be used as channels. Thus, the nozzles can also be arranged finely and densely, and the channels can also be arranged finely and densely in accordance with a plurality of the nozzles arranged densely. As a result, the liquid discharge head using the channel forming substrate can be reduced in size and realize high-density and high-definition drawing. Furthermore, the channel forming substrate described in this case includes any substrate, such as a nozzle plate, a cavity forming substrate, or a reservoir forming substrate, which forms a channel in the liquid discharge head.

### BRIEF DESCRIPTION OF THE DRAWINGS

The invention will be described with reference to the accompanying drawings, wherein like numbers reference like elements.

FIG. 1 is a flowchart illustrating through-hole processing processes according to a first embodiment.

FIGS. 2A to 2G are cross-sectional views for schematically illustrating a through-hole forming method according to the first embodiment, in chronological order.

FIGS. 3A and 3B are views for explaining a laser beam drilling processing.

FIG. 4 is a flowchart illustrating through-hole processing processes according to a second embodiment.

FIGS. 5A to 5G are cross-sectional views for schematically illustrating a through-hole forming method according to the second embodiment, in chronological order.

FIG. 6 is a flowchart illustrating through-hole processing processes according to a third embodiment.

FIGS. 7A to 7G are cross-sectional views for schematically illustrating a through-hole forming method according to the third embodiment, in chronological order.

FIG. 8 is a cross-sectional view of an element embedded substrate to which the through-hole according to the embodiments is applied.

FIG. 9 is a cross-sectional view of a liquid discharge head to which the through-hole according to the embodiments is applied.

### DESCRIPTION OF EXEMPLARY EMBODIMENTS

A through-hole forming method as a silicon substrate processing method is preferably applied to a silicon through electrode or a channel forming substrate of a liquid discharge device, for example. A high-density and high-definition pattern drawing capability, for example, is required for the liquid discharge device including a plurality of nozzles through which droplets are discharged. Thus, it is necessary to densely arrange a plurality of nozzles for realizing high-density and high-definition drawing. In recent years, a device having a dot density (a nozzle pitch) higher than 600 dpi (dots per inch, about 26.3 μm pitch) has been required. The dot density is a basic standard of drawing. Therefore, even in the channel forming substrate which has channels corresponding to nozzles, it is necessary to form fine-diameter through holes at fine pitches.

Hereinafter, the through-hole forming method as a silicon substrate processing method, which is applied to this, will be described with reference to the accompanying drawings. Furthermore, in the reference drawings of the following description, the vertical and horizontal scale of some members or portions is different from the actual scale, for the reason of convenience in description and drawing.

### Through-Hole Forming Method According to First Embodiment

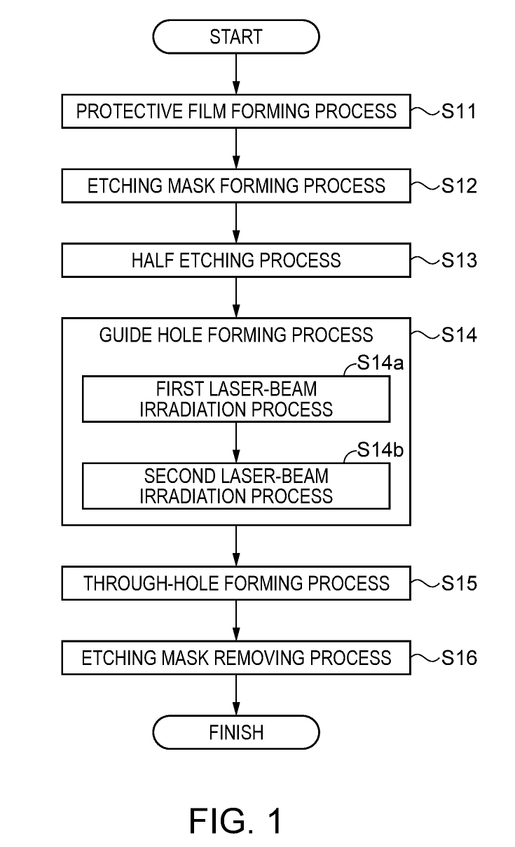

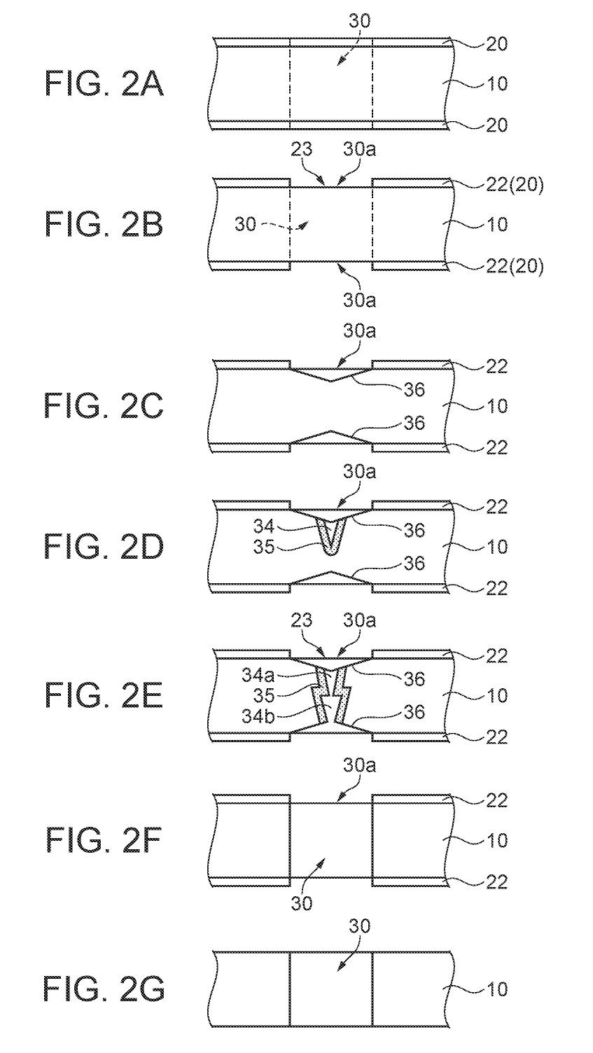

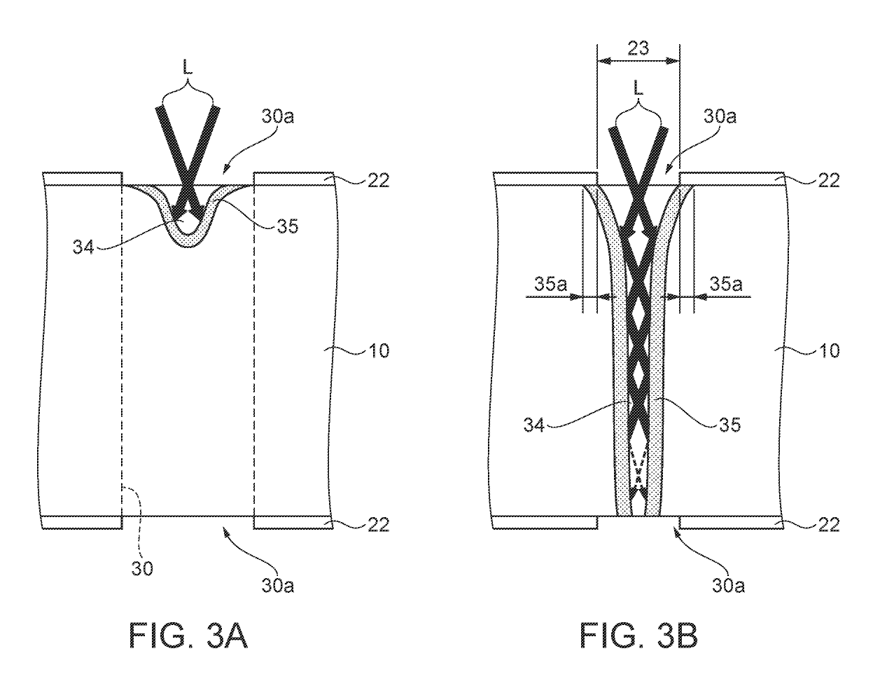

First, a through-hole forming method according to a first embodiment will be described with reference to FIGS. 1 to 3B. FIG. 1 is a flowchart illustrating through-hole processing processes according to the first embodiment, and FIGS. 2A to 2G are cross-sectional views for schematically illustrating a through-hole forming method, in chronological order. FIGS. 3A and 3B are views for explaining a laser beam drilling processing. Hereinafter, according to the flowchart illustrated in FIG. 1, a description will follow with reference to FIGS. 2A to 3B.

In a protective film forming process S11 illustrated in FIG. 1, silicon oxide films are deposited over the entire front and back surfaces of a silicon single crystal substrate 10 (hereinafter, referred to as the substrate 10) by the thermal oxidation method, as illustrated in FIG. 2A, and thus an etching protective film 20 is formed. It is preferable that the thickness of the etching protective film 20 is set to be approximately 1 μm.

Next, in an etching mask forming process S12, the etching protective film 20 is formed, by means of photolithography, into a mask shape to perform an etching process described below. In the etching mask forming process S12, first, the etching protective film 20 deposited in the protective film forming process S11 is coated with a resist agent by a spin coat method or the like. Then, part of the resist agent, which corresponds to a forming range of an opening portion 30a of a through-hole 30, is subjected to exposure and development, and thus part of the resist agent, which corresponds to an exposed portion, is removed. Subsequently, the substrate 10 is immersed in buffered fluoric acid solution, and thus etching masks 22 used in an etching process of the substrate 10 are formed on both surfaces of the substrate 10, as illustrated in FIG. 2B. The etching mask 22 includes a through-hole forming opening portion 23 of the etching protective film 20, which is formed by removing the opening portion 30a of the through-hole 30.

Next, in a half etching process S13, a 20 mass % KOH aqueous solution, for example, is applied as an etchant and used by being heated to 80° C. The substrate 10 including the etching mask 22 is immersed in the etchant for a predetermined amount of time. As a result, funnel-shaped dug-in portions 36 having arbitrary depths are respectively formed on both surfaces of the substrate 10, as illustrated in FIG. 2C. In addition, this half etching process S13 is optional.

Next, in a guide hole forming process S14, a perforation 34 as an etching guide hole is formed in the vicinity of the center of one (a front surface side) of the funnel-shaped dug-in portions 36 formed on the substrate 10.

Here, a principle of forming the perforation 34 by a laser-beam irradiation will be described with reference to FIGS. 3A and 3B. A laser beam L is focused and applied to part of the surface of the substrate 10, which is exposed through the through-hole forming opening portion 23 of the etching mask 22, as illustrated in FIG. 3A. Part of the substrate 10, which is irradiated with the laser beam L, is melted and evaporated by heat of the laser beam L. Therefore, the perforation 34 having a substantially inverted spindle shape is formed in the substrate 10 to be long in a laser-beam L irradiation direction. At this time, thermal reforming progresses by thermal energy of the laser beam L, and thus a thermal reforming portion 35 is formed in the vicinity of the perforation 34. In addition, the thermal reforming portion 35 formed in the substrate 10 is a portion of the substrate 10 which is different from the surrounding portion in density, refractive index, mechanical strength, crystal arrangement, and other physical properties, for example. The thermal reforming portion 35 can be removed easily by etching.

The laser beam L applied to the perforation 34 is successively and multiply reflected on an inner surface of the precedently-formed perforation 34 and gradually advances to the deep portion, as illustrated in FIG. 3B. As a result, a deeper perforation 34 is formed. The deeper the perforation 34 is, the smaller the reaching energy of the laser beam L is. Particularly, in a case where an aspect ratio is large, a large amount of energy is required in order to penetrate the substrate 10. Peripheral (radial) thermal reforming is likely to progress to the deeper layer, because heat quantity owing to the laser beam L is large in the vicinity of a laser-beam L incident surface. As a result, in some cases, the thermal reforming progresses to the layer deeper than the through-hole forming opening portion 23 of the etching mask 22 (over reforming 35a).

Furthermore, it is preferable that the applied laser beam L has a wavelength band allowing the laser beam L to be transmitted through single crystal silicon, which is a material forming the substrate 10. However, in a case where the perforation 34 having a minute diameter is formed on the single crystal silicon, plasma is generated before the single crystal silicon is melted and evaporated. This plasma having high density is retained in the perforation 34. The laser beam L is absorbed into the plasma, and thus the laser beam energy is likely to be reduced. Particularly, the longer the wavelength of the laser beam L is, the easier the absorption of the laser beam L by the plasma is. Thus, it is preferable that the laser beam L is a short-wavelength laser beam, such as a SHG laser beam with a 532 nm wavelength, a THG laser beam with a 355 nm wavelength, and an FHG laser beam with a 266 nm wavelength. However, a type of laser beam is not particularly limited and can be arbitrarily selected based on various set conditions, such as irradiation energy or irradiation time.

In the first embodiment, the guide hole forming process S14 is performed in a manner in which the laser beam L is applied a plurality of times, as illustrated in FIG. 1. In the following description, a case in which the laser beam L is applied twice, for example, is exemplified. Further, the two times of irradiation processes are referred to as a first laser-beam irradiation process S14a and a second laser-beam irradiation process S14b.

In the first laser-beam irradiation process S14a, the laser beam L is focused and applied, using a laser processing device (not illustrated), in the vicinity of a bottom portion of the funnel-shaped dug-in portion 36 which is formed in the opening portion 30a of the through-hole 30. Part of the substrate 10, which is irradiated with the laser beam L, is melted and evaporated by the heat of the laser beam L. The laser beam L which is applied to a first perforation 34a having a substantially inverted spindle shape is successively reflected (multiply reflected) on the inner surface of the precedently-formed first perforation 34a and gradually advances to the deep portion. The irradiation of the laser beam L is stopped when the depth of the first perforation 34a reaches about half of the thickness of the substrate 10.

At this time, thermal reforming progresses by the thermal energy of the laser beam L, and thus the thermal reforming portion 35 is formed in the vicinity of the first perforation 34a. As a result, the first perforation 34a having a substantially inverted spindle shape is formed on the silicon substrate 10 to be long in the laser-beam L irradiation direction, as illustrated in FIG. 2D.

Then, the cooling period lasts for a while.

Then, in the second laser-beam irradiation process S14b, the laser beam L is applied again in a state where energy of the laser beam L is set to be greater than that in the first laser-beam irradiation process S14a. The inner surface of the first perforation 34a is stabilized by the cooling period. Further, the laser beam L having greater energy is applied, and thus a second perforation 34b of which a starting point is in the vicinity of a tip (the bottom portion) of the first perforation 34a formed in the first laser-beam irradiation process S14a is formed, as similar to the case of the first laser-beam irradiation process S14a.

The laser beam L which is applied to the first perforation 34a and the second perforation 34b is successively reflected (multiply reflected) on the inner surfaces of the precedently-formed first perforation 34a and second perforation 34b and reaches the tip of the second perforation 34b. As a result, the second perforation 34b gradually advances to the deeper layer and penetrates to the opposite surface, as illustrated in FIG. 2E. Thus, forming of the etching guide hole is completed.

Furthermore, although a case in which the guide hole forming process S14 is divided into two processes is exemplified in the description of the first embodiment, the process is not limited thereto. The optimal number of processes can be selected in consideration of the diameter of the through-hole 30 and the thickness of the substrate 10.

Next, in a through-hole forming process S15, similarly, a 20 mass % KOH aqueous solution, for example, is applied as the etchant and used by being heated to 80° C. The substrate 10 in which the first perforation 34a and the second perforation 34b are formed and which includes the etching mask 22 is immersed in the etchant for a predetermined amount of time. As a result, the through-hole 30 passing through both surfaces of the substrate 10 is formed, as illustrated in FIG. 2F. Furthermore, in these etching processes, the first perforation 34a and the second perforation 34b which include the thermal reforming portions 35 function as an etching guide hole. The reason for this is because the etching anisotropy of the thermal reforming portion 35 is smaller than that of other portions of the thermal reforming portion 35 and the etching rate thereof is high (easy to etch).

Then, in an etching mask removing process S16, the etching mask 22 (the etching protective film 20) on the surface of the substrate 10 is coated with a resist agent by a spin coat method or the like. Then, the resist agent is subjected to exposure and development, and thus the resist agent on the exposure portion is removed. Subsequently, the substrate 10 is immersed in buffered fluoric acid solution, and thus the etching mask 22 is removed. As a result, forming of the substrate 10 in which the through-hole 30 is formed is completed, as illustrated in FIG. 2G.

Description of effects of the first embodiment will follow.

In the through-hole forming method described above, to form the perforation 34, irradiation of the laser beam L is performed a plurality of separate times from the same direction. In addition, the cooling period is provided every time a laser-beam irradiation process (the first laser-beam irradiation process S14a) is finished. Thus, the inner surface of the first perforation 34a, which includes the entrance portion, is stabilized, and thus it is easy for the laser beam L to be multiply reflected and advance to the deep portion of the first perforation 34a, in the subsequent laser-beam irradiation process (the second laser-beam irradiation process S14b). As a result, it is possible to suppress the entrance portion of the precedently-formed first perforation 34a from increasing in diameter and suppress thermal reforming from progressing. As a result, the second perforation 34b of which a starting point is in the vicinity of the bottom portion of the first perforation 34a is formed. That is, the laser-beam irradiation process is divided into a plurality of processes, and thus it is possible to penetrate the substrate 10 while suppressing the thermal reforming of the perforation 34 from progressing to the deeper layer in, for example, the through-hole forming opening portion 23 on the etching mask 22, which defines the diameter of the entrance portion of the through-hole 30.

Furthermore, in the through-hole forming process S15, the perforation 34 as an etching guide hole and the thermal reformed portion surrounding the perforation 34 are subjected to etching treatment, and thus the through-hole 30 is formed. The entrance portion of the perforation 34 is suppressed from increasing in diameter, and the thermal reforming of the perforation 34 is suppressed from excessively progressing. Thus, it is possible to suppress the through-hole 30 from increasing in bore diameter. As a result, it is possible to densely arrange the through-holes 30 having minute diameters on the substrate 10.

### Through-Hole Forming Method According to Second Embodiment

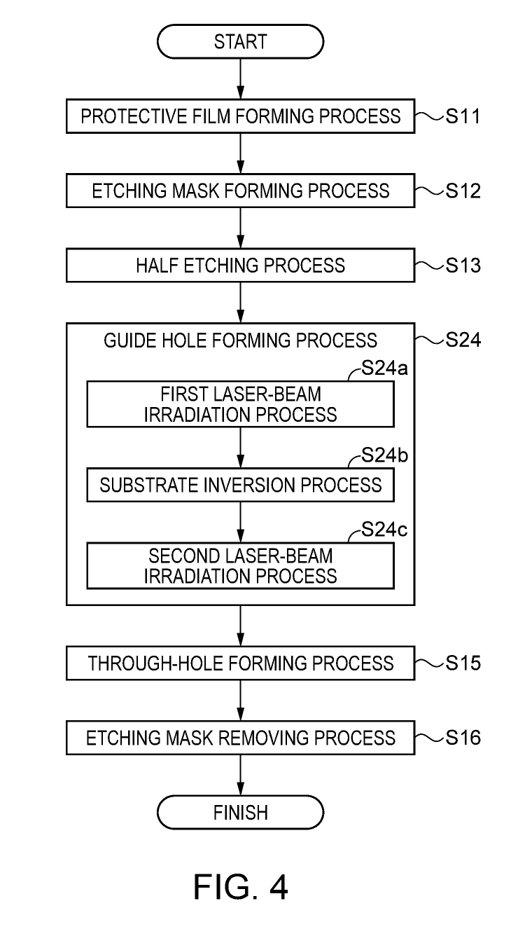

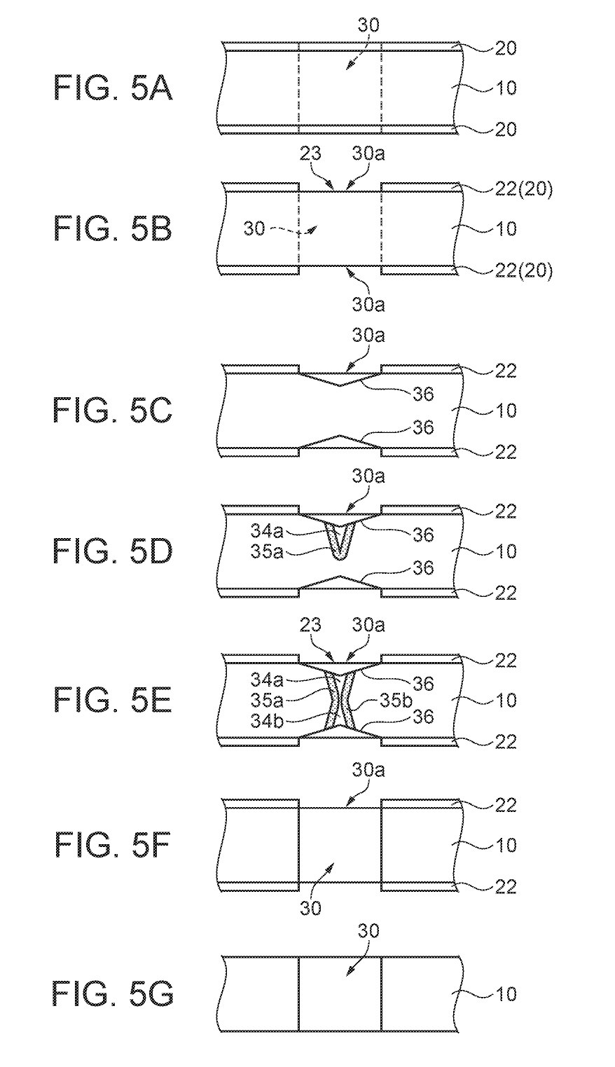

Next, a through-hole forming method according to a second embodiment will be described with reference to FIGS. 4 to 5G. FIG. 4 is a flowchart illustrating through-hole processing processes according to the second embodiment, and FIGS. 5A to 5G are cross-sectional views for schematically illustrating a through-hole forming method, in chronological order. Hereinafter, according to the flowchart illustrated in FIG. 4, a description will follow with reference to FIGS. 5A to 5G. In addition, the same reference numerals are given to the same configurations as those in the first embodiment, and the same descriptions as those in the first embodiment will not be repeated.

In the through-hole forming method according to the second embodiment, processing processes from the protective film forming process S11 to the half etching process S13 are the same as those in the first embodiment, as illustrated in FIG. 4. In the following description, a case in which the laser beam L is applied twice, for example, is exemplified as a guide hole forming process S24 of the second embodiment. Further, the two times of irradiation processes are referred to as a first laser-beam irradiation process S24a and a second laser-beam irradiation process S24c.

In the first laser-beam irradiation process S24a, the first perforation 34a as an etching guide hole is formed in the vicinity of the center of one (that is, a front surface side) funnel-shaped dug-in portion 36 formed in the substrate 10. That is, the laser beam L is focused and applied, using the laser processing device (not illustrated), in the vicinity of a bottom portion of one funnel-shaped dug-in portion 36 which is formed in one opening portion 30a of the through-hole 30.

Part of the silicon substrate 10, which is irradiated with the laser beam L, is melted and evaporated by the heat of the laser beam L. Thus, the first perforation 34a having a substantially inverted spindle shape is formed in the silicon substrate 10 to be long in the laser-beam L irradiation direction. The laser beam L which is applied to the first perforation 34a having a substantially inverted spindle shape is successively reflected (multiply reflected) on the inner surface of the precedently-formed first perforation 34a and gradually advances to the deep portion. Irradiation with the laser beam L is stopped when the depth of the first perforation 34a reaches about half of the thickness of the substrate 10. At this time, thermal reforming progresses by the thermal energy of the laser beam L, and thus the thermal reforming portion 35a is formed in the vicinity of the first perforation 34a. As a result, the first perforation 34a having a substantially inverted spindle shape is formed to be long in the laser-beam L irradiation direction, as illustrated in FIG. 5D.

In a substrate inversion process S24b illustrated in FIG. 4, the front and back surfaces of the substrate 10 are turned over and placed on the laser processing device such that a surface opposite the surface (the front surface) on which the first perforation 34a is formed in the first laser-beam irradiation process S24a is irradiated with the laser beam L.

In the second laser-beam irradiation process S24c, the second perforation 34b as an etching guide hole is formed in the vicinity of the center of the other (a back surface side) funnel-shaped dug-in portion 36 formed in the substrate 10. That is, the laser beam L is focused and applied, using the laser processing device (not illustrated), in the vicinity of a bottom portion of the funnel-shaped dug-in portion 36 which is formed in the other opening portion 30a of the through-hole 30.

Part of the silicon substrate 10, which is irradiated with the laser beam L, is melted and evaporated by the heat of the laser beam L. Thus, the second perforation 34b having a substantially inverted spindle shape is formed in the silicon substrate 10 to be long in the laser-beam L irradiation direction. The laser beam L which is applied to the second perforation 34b having a substantially inverted spindle shape is successively reflected (multiply reflected) on the inner surface of the precedently-formed second perforation 34b and gradually advances to the deep portion. Irradiation with the laser beam L is stopped when the depth of the second perforation 34b reaches about half of the thickness of the substrate 10. At this time, thermal reforming progresses by the thermal energy of the laser beam L, and thus a thermal reforming portion 35b is formed in the vicinity of the second perforation 34b.

In this case, it is preferable that a hollow portion of the first perforation 34a bored downward and a hollow portion of the second perforation 34b bored downward have portions overlapping in the thickness direction of the substrate 10. As a result, the hollow portion of the first perforation 34a and the hollow portion of the second perforation 34b overlap with each other, and thus the overlapping hollow portion passes through the substrate 10, as illustrated in FIG. 5E. As a result, forming of the etching guide hole is completed. For the reasons of clear illustration, FIG. 5E illustrates the same direction as those in FIGS. 5A and 5F. Furthermore, in this case, the thermal reforming portion 35a of the first perforation 34a and the thermal reforming portion 35b of the second perforation 34b may have portions overlapping in the thickness direction of the substrate 10. The thermal reforming portion 35a and the thermal reforming portion 35b have a high etching rate, and thus these thermal reforming portions sufficiently function as an etching guide hole even when not passing through the substrate 10.

Then, as similar to the first embodiment, in the through-hole forming process S15, similarly, a 20 mass % KOH aqueous solution, for example, is applied as the etchant and used by being heated to 80° C. The substrate 10 in which the first perforation 34a and the second perforation 34b are formed and which includes the etching mask 22 is immersed in the etchant for a predetermined amount of time. As a result, the through-hole 30 passing through both surfaces of the substrate 10 is formed, as illustrated in FIG. 5F. Furthermore, in these etching processes, the first perforation 34a and the second perforation 34b which include the thermal reforming portions 35 function as an etching guide hole. The reason for this is because the etching anisotropy of the thermal reforming portion 35 is smaller than that of other portions and the etching rate thereof is high.

Next, in the etching mask removing process S16, the etching mask 22 on the surface of the substrate 10 is coated with a resist agent by a spin coat method or the like. Then, the resist agent is subjected to exposure and development, and thus the resist agent on the exposure portion is removed. Subsequently, the substrate 10 is immersed in buffered fluoric acid solution, and thus the etching mask 22 is removed. As a result, forming of the substrate 10 in which the through-hole is formed is completed, as illustrated in FIG. 5G.

Furthermore, although a case in which the irradiation with the laser beam L is performed twice is exemplified in the description of the second embodiment, the number of irradiation times is not limited thereto. The irradiation of the laser beam L may be performed two or more times.

Description of effects of the second embodiment will follow.

(1) In the through-hole forming method described above, to form the perforation 34, irradiation of the laser beam L is performed a plurality of separate times from the different direction of the substrate. In other words, in the second embodiment, the precedent laser-beam irradiation process (the first laser-beam irradiation process S24a) is performed on the front surface of the substrate 10 and the subsequent laser-beam irradiation process (the second laser-beam irradiation process S24c) is performed on the back surface of the substrate 10. Next, the tip portion of the first perforation 34a and the tip portion of the second perforation 34b are overlapped in the thickness direction of the substrate 10. Thus, it is possible to penetrate the substrate 10 while suppressing the thermal reforming from progressing to the deeper layer, which is caused by a concentration of the energy of the laser-beam L on the entrance portion of either one of the perforations 34.

Furthermore, in the through-hole forming process S15, the perforation 34 as an etching guide hole and the thermal reformed portion surrounding the perforation 34 are subjected to etching treatment, and thus the through-hole 30 is formed. The entrance portion of the perforation 34 is suppressed from increasing in diameter, and the thermal reforming of the perforation 34 is suppressed from excessively progressing. Thus, it is possible to suppress the through-hole 30 from increasing in bore diameter. As a result, it is possible to densely arrange the through-holes 30 having minute diameters on the substrate 10.

(2) According to the through-hole forming method described above, in the first laser-beam irradiation process S24a and the second laser-beam irradiation process S24c, a tip portion of the first perforation 34a and a tip portion of the second perforation 34b overlap in the thickness direction of the substrate 10. The only requirement of these overlap portions is that the hollow portions of the respective perforations 34 are superimposed on each other. It is possible to cause the perforations 34 to pass through the substrate 10, even when the positions of the perforations 34 are misaligned in a plane direction, in the substrate inversion process S24b, the first laser-beam irradiation process S24a, or the second laser-beam irradiation process S24c. That is, it is possible to reduce the influence of mechanical precision, such as positional alignment in operation.

### Through-Hole Forming Method According to Third Embodiment

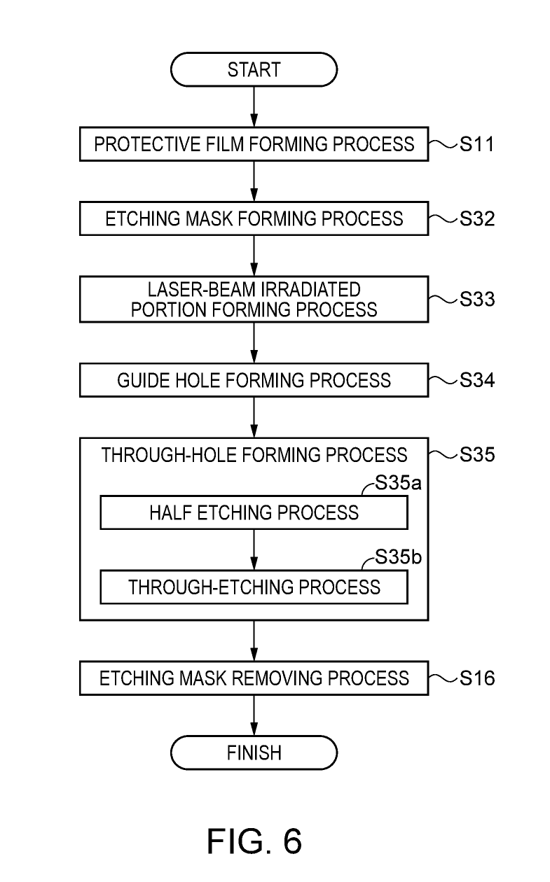

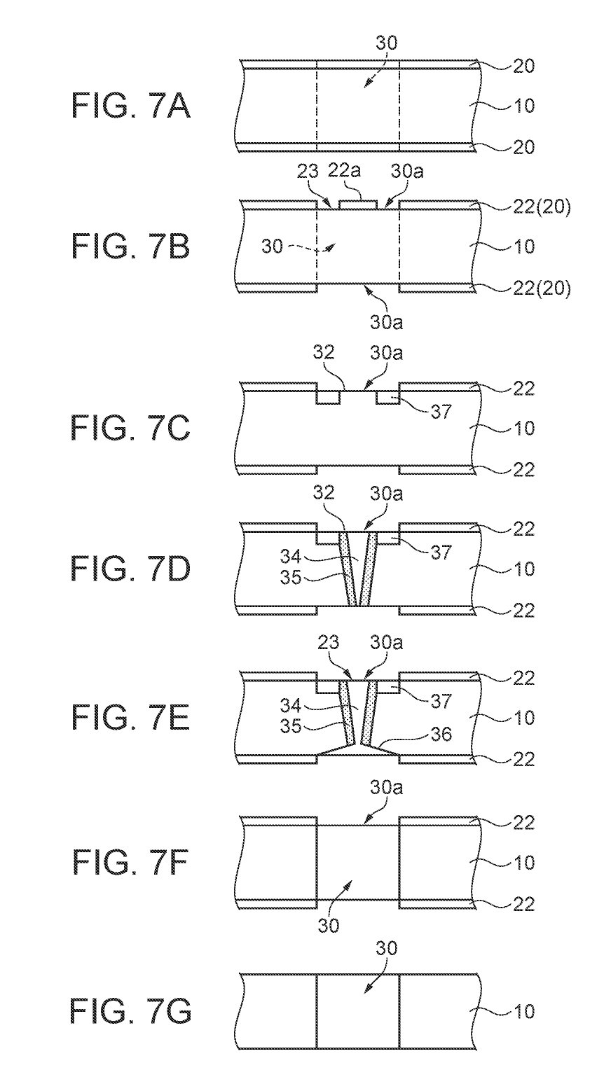

Here, a through-hole forming method according to a third embodiment will be described with reference to FIGS. 6 to 7G. FIG. 6 is a flowchart illustrating through-hole processing processes according to the third embodiment, and FIGS. 7A to 7G are cross-sectional views for schematically illustrating a through-hole forming method, in chronological order. Hereinafter, according to the flowchart illustrated in FIG. 6, a description will follow with reference to FIGS. 7A to 7G. In addition, the same reference numerals are given to the same configurations and descriptions as those in the first and second embodiments, and the descriptions thereof will not be repeated.

In the through-hole forming method according to the third embodiment, the protective film forming process S11 is the same as that in the first embodiment or the second embodiment, as illustrated in FIG. 6.

Next, in an etching mask forming process S32, the etching protective film 20 is formed, by means of photolithography, into a mask shape to perform first and second etching processes described below. In the etching mask forming process S32, first, the etching protective film 20 deposited in the protective film forming process S11 is coated with a resist agent by a spin coat method or the like. Then, part of the coated resist agent, which corresponds to a range separated, by a predetermined distance, from an outer peripheral portion of the opening portion 30a of the through-hole 30, is subjected to exposure and development, and thus the resist agent on the exposure portion is removed such that a laser-beam irradiated portion 32 which is formed in an island shape and has a predetermined size is formed in the center of a forming range of the opening portion 30a of the through-hole 30. Subsequently, the substrate 10 is immersed in buffered fluoric acid solution, and thus the etching masks 22 used in an etching process of the substrate 10 are formed, as illustrated in FIG. 7B. The etching mask 22 in which parts of the etching protective film 20 are removed includes the through-hole forming opening portion 23. A laser-beam irradiated portion forming etching protective film 22a formed in an island shape is provided with the through-hole forming opening portion 23.

Next, in a laser-beam irradiated portion forming process S33, part of the substrate 10, which corresponds to a removed range of the etching protective film 20 in the etching mask forming process S32, namely, a range between the laser-beam irradiated portion 32 forming etching protective film 22a having an island shape and the etching protective film 20 located outside the through-hole forming opening portion 23, is removed at a predetermined depth by means of etching, such as a dry etching method (the first etching process). As a result, the opening portion 30a is formed to have the laser-beam irradiated portion 32 formed in an island shape around which a groove 37 (a gap, see FIG. 7C) is formed. Examples of the dry etching method may include a so-called reactive gas etching method in which material is exposed to fluorine-based reaction gas and a so-called reactive ion etching method in which etching is performed in a state where gas is ionized or radicalized by plasma.

Then, the laser-beam irradiated portion 32 forming etching protective film 22a having an island shape is coated with a resist agent. Subsequently, the resist agent is subjected to exposure and development, and thus the resist agent on the exposure portion is removed (see FIG. 7C).

Next, in the guide hole forming process S34, the perforation 34 as an etching guide hole is formed in the vicinity of the center of the through-hole 30 formed in the substrate 10, that is, in the vicinity of the center of the laser-beam irradiated portion 32 having an island shape. The laser beam L is focused and applied, using the laser processing device (not illustrated), on a surface of the laser-beam irradiated portion 32 formed in the opening portion 30a of the through-hole 30. Part of the silicon substrate 10, which is irradiated with the laser beam L, is melted and evaporated by the heat of the laser beam L. Thus, the perforation 34 having a substantially inverted spindle shape is formed in the silicon substrate 10 to be long in the laser-beam L irradiation direction.

The laser beam L which is applied to the perforation having a substantially inverted spindle shape is successively reflected on the inner surface of the precedently-formed perforation 34 and reaches the tip of the perforation 34. As a result, the perforation 34 gradually advances to the deeper layer and penetrates to the opposite surface, as illustrated in FIG. 7D. At this time, thermal reforming progresses by the thermal energy of the laser beam L, and thus the thermal reforming portion 35 is formed in the vicinity of the perforation 34. However, in the thermal reforming portion 35, the groove 37 is formed around the laser-beam irradiated portion 32, and thus the air in the groove portion functions as a heat insulator. Accordingly, it is difficult for the thermal reforming portion 35 to progress to further outside than the laser-beam irradiated portion 32. The thermal reforming portion 35 formed in the substrate 10 is a portion of the substrate 10 which is different from the surrounding portion in density, refractive index, mechanical strength, crystal arrangement, and other physical properties, for example. The thermal reforming portion 35 can be removed easily by etching.

In a through-hole forming process S35, the perforation 34 which is formed in the guide hole forming process S34 and functions as an etching guide hole is formed in the through-hole 30 by etching (the second etching process). In this embodiment, to accurately form a through-hole having a minute diameter, the through-hole forming process S35 is performed in such a manner that etching process is carried out twice in the two separate processes, that is, in a half etching process S35a and a through-etching process S35b, for example.

In the half etching process S35a, a 20 mass % KOH aqueous solution, for example, is applied as the etchant and used by being heated to 80° C. The substrate 10 in which the perforation 34 is formed and which includes the etching mask 22 is immersed in the etchant for a predetermined amount of time. As a result, the funnel-shaped dug-in portion 36 having an arbitrary depth from the back surface of the substrate 10 is formed, as illustrated in FIG. 7E. In addition, this half etching process S35a is optional.

Subsequently, in the through etching process S35b, similarly, a 20 mass % KOH aqueous solution, for example, is applied as the etchant and used by being heated to 80° C. The substrate 10 in which the funnel-shaped dug-in portion 36 is formed and which includes the etching mask 22 is immersed in the etchant for a period longer than the immersion time in the half etching process S35a. As a result, the through-hole 30 passing through both surfaces of the substrate 10 is formed, as illustrated in FIG. 7F. Furthermore, in these etching processes, the perforation 34 having the thermal reforming portion 35 functions as an etching guide hole. The reason for this is because the etching anisotropy of the thermal reforming portion 35 is smaller than that of other portions of the thermal reforming portion 35 and the etching rate thereof is high (easy to etch).

Next, in the etching mask removing process S16, the etching mask 22 on the surface of the substrate 10 is coated with a resist agent by a spin coat method or the like. Then, the resist agent is subjected to exposure and development, and thus the resist agent on the exposure portion is removed. Subsequently, the substrate 10 is immersed in buffered fluoric acid solution, and thus the etching mask 22 is removed. As a result, forming of the substrate 10 in which the through-hole 30 is formed is completed, as illustrated in FIG. 7G.

Description of effects of the third embodiment will follow.

In the through-hole forming method described above, the island-shaped laser-beam irradiated portion 32 which has a predetermined size and is formed at a position at which the opening portion 30a of the through-hole 30 is formed. In other words, the laser-beam irradiated portion 32 includes the groove 37 (the gap) having a predetermined width from the inner surface of the through-hole 30. Thus, even when the laser-beam irradiated portion 32 is irradiated with the laser beam L to form the perforation 34, the thermal energy of the laser beam L is blocked by the groove 37 (the gap), and thus it is difficult for the thermal energy of the laser beam L to be transmitted to the inner surface of the through-hole 30. As a result, it is possible to form the perforation 34 passing through the substrate 10 while preventing, even in an incident surface of the laser beam L (the opening portion 30a), thermal reforming from progressing in the radial direction of the through-hole 30.

Furthermore, in the through-hole forming process S35, the perforation 34 as an etching guide hole and the thermal reformed portion surrounding the perforation 34 are subjected to etching treatment, and thus the through-hole 30 is formed. The entrance portion of the perforation 34 is suppressed from increasing in diameter, and the thermal reforming of the perforation 34 is suppressed from excessively progressing. Thus, it is possible to suppress the through-hole 30 from increasing in bore diameter. As a result, it is possible to densely arrange the through-holes 30 having minute diameters on the substrate 10.

### Element Embedded Substrate

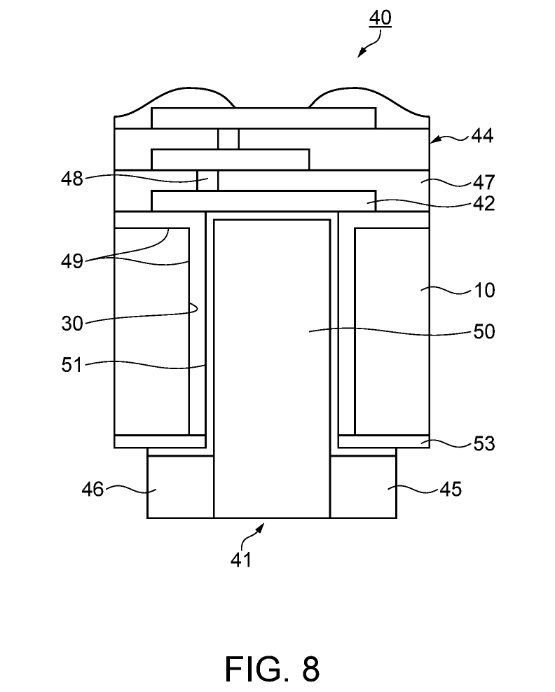

Here, as an application example of the through-hole which is formed by methods described above, an element embedded substrate having a silicon through electrode will be described with reference to FIG. 8. Furthermore, the silicon through electrode is apiece of mounting technology of a semiconductor as an electronic component. The silicon through electrode is an electrode which vertically passes through the inner portion of a silicon-based semiconductor chip. For the reason of miniaturization, a plurality of chips (referred to as an element embedded substrate, hereinafter) are superimposed on each other to forma single three-dimensional mounting package or a single three-dimensional integrated circuit. In this case, the silicon through electrode connects an upper element embedded substrate and a lower element embedded substrate. Hereinafter, by a way of example, an element embedded substrate will be described as the silicon through electrode. FIG. 8 is a cross-sectional view of the element embedded substrate in which the through-hole according to the embodiments described above is applied.

A silicon through electrode 41 (referred to as a through electrode 41, hereinafter) formed on the substrate 10 (the single crystal silicon substrate), which is made using the through-hole 30 formed by methods described above, is provided in an element embedded substrate 40, as illustrated in FIG. 8. An element circuit 44 which is connected to the through electrode 41 via a wiring layer 42 is provided on a front surface side of the substrate 10, which is one end side of the through electrode 41. In contrast, the other end side of the through electrode 41 protrudes from the back surface of the substrate 10, and an external electrode terminal 45 is formed in the protrusion so that a bump electrode 46 is formed. Accordingly, it is possible to manufacture one package having a small size by vertically superimposing one element embedded substrate 40 on the other element embedded substrate 40.

More specifically, the configuration is as follows. The through electrode 41 extends from the back surface of the substrate 10 to the wiring layer 42 formed on the front surface of the substrate 10, that is, the surface on which the element circuit 44 is formed. Further, the wiring layer 42 is electrically connected with the external electrode terminal 45 formed on the back surface of the substrate 10. In addition, the element circuits 44 which are separated from each other by an insulation film 47 are formed on the wiring layer 42. The wiring layer 42 is electrically connected with the element circuit 44 through a via wiring 48 formed on the insulation film 47. In addition, the wiring layer 42 may be formed by a plurality of superimposed metal layers.

In the through electrode 41, an inner wall of the through-hole 30 which is formed in the substrate 10 and functions as a via hole is covered with a first insulation layer 49 formed of inorganic material, such as a silicon oxide film. This first insulation layer 49 is formed by thermal oxidation at an environmental temperature of approximately 1000° C. The first insulation layer 49 is imposed between the substrate 10 and the element circuit 44 (the wiring layer 42, specifically) and continuously extends over an inner wall surface of the through-hole 30. The first insulation layer 49 is an insulation film formed by thermal oxidation. Thus, a single first insulation layer 49, which is densely formed and even in thickness, is formed over a surface of the substrate 10, on which the element circuit 44 is formed, and the inner wall surface of the through-hole 30. The thickness of the first insulation layer 49 is about 5% to 10% of the diameter of the through-hole 30. Thus, if the diameter of the through-hole 30 is about 20 the thickness of the first insulation layer 49 is about 1 μm to 2 μm. Therefore, a corner portion of the through-hole 30 which is on the wiring layer 42 side, is covered with the first insulation layer 49 which is dense and thick, and thus the corner portion in which electric breakdown is likely to occur is improved in an insulation property. Accordingly, a leakage-current suppressing effect is great.

In addition, a metal film (referred to as a barrier layer 51, hereinafter), such as a film formed of TiW, is formed over the wiring layer 42 of the element circuit 44, which faces an opening of the through-hole 30, and the inner wall of the first insulation layer 49. The barrier layer 51 functions as a barrier and adhesion layer for preventing an embedded semiconductor 50, which is formed over the inner circumferences of the wiring layer 42 and the first insulation layer 49, from diffusing throughout the substrate 10.

The embedded semiconductor 50 formed of Cu, Ni, or Au, for example, is formed in the inner wall of the barrier layer 51 in an embedded manner. A hollow portion of a hole surrounded by the barrier layer 51 may be completely filled with the embedded semiconductor 50. Alternatively, the barrier layer 51 may be formed in a film shape covering the inner wall of the hollow portion of the hole. In this case, it is preferable that other insulation material, such as resin, is embedded in the hole portion within the conductor film for the reason of reinforcement.

Furthermore, to insulate a back-surface side via corner portion, a second insulation layer 53 formed of, for example, inorganic material, such as resin or silicon oxide is formed on the back surface opposite the surface of the substrate 10, on which the element circuit 44 is formed. The second insulation layer 53 is formed continuously with the first insulation layer 49. In addition, the embedded semiconductor 50 protrudes from an outer surface of the second insulation layer 53 toward a back surface side of the substrate 10, and the external electrode terminal 45 is formed to be in contact with the protrusion. As a result, the bump electrode 46 is formed. Such an element embedded substrate 40 is applied to a crystal oscillator package, an infrared sensor, or the like.

In the element embedded substrate 40 described above, the through electrode 41 is made using the through-hole 30 formed by the methods according to the embodiments described above. In the methods according to the embodiments described above, it is possible to suppress the thermal reforming from progressing around the portion irradiated with the laser beam L, even when the substrate 10 is thick. Furthermore, it is possible to densely arrange the through-holes 30 having minute diameters. In other words, it is possible to densely arrange the through electrodes 41 having minute diameters. Accordingly, it is possible to realize high-density mounting, and thus the more compact element embedded substrate 40 can be provided.

### Channel Forming Substrate

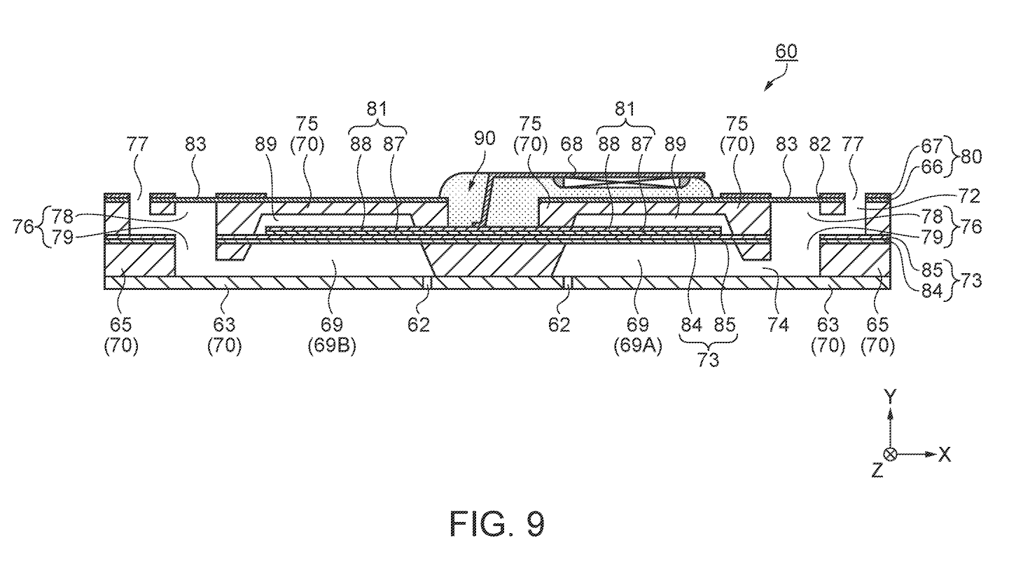

Here, as an application example of the through-hole which is formed by methods described above, a channel forming substrate will be described with reference to FIG. 9. Furthermore, the channel forming substrate is applied to a liquid discharge head which discharges functional liquid, for example, as droplets. The liquid discharge head can print a desired image on a surface of a discharge target object by relatively moving on the discharge target object and selectively discharging droplets. Hereinafter, by a way of example, a liquid discharge head will be described as the channel forming substrate. FIG. 9 is a cross-sectional view of the liquid discharge head in which the through-hole according to the embodiments described above is applied.

A liquid discharge head 60 is configured to have a nozzle plate 63 on which nozzles 62 are formed to discharge droplets, a cavity forming substrate 65 which is connected to an upper surface of the nozzle plate 63 and in which functional liquid is accumulated, a diaphragm 73 which is connected to an upper surface of the cavity forming substrate 65 and displaced in accordance with driving of a piezoelectric element (a driving element) 81, a reservoir forming substrate 75 which is connected to an upper surface of the diaphragm 73 and forms a reservoir 76, and a flexible substrate 68 which has flexibility and is provided on an upper surface side of the reservoir forming substrate 75, as illustrated in FIG. 9. In this case, a channel forming substrate 70 includes any substrate having a plurality of channels through which the functional liquid flows. The channel forming substrate 70 includes, at least, the nozzle plate 63, the cavity forming substrate 65, the reservoir forming substrate 75, and the like.

A single crystal silicon substrate is preferably applied as material forming the cavity forming substrate 65, and the single crystal silicon substrate is processed by the combination of the through-hole forming methods described above and an anisotropic etching method. The cavity forming substrate 65 forms a partition for partitioning cavities 69 in which the functional liquid is accumulated. Channels through which the functional liquid flows are formed in the cavity forming substrate 65. A lower surface side of the cavity forming substrate 65, in terms of drawings, is open. The nozzle plate 63 is connected to a lower surface of the cavity forming substrate 65 so as to cover the opening. The lower surface of the cavity forming substrate 65 and the nozzle plate 63 are fixed by an adhesive, a heat welding film, or the like.

Accordingly, a plurality of the cavities 69 are formed by space surrounded by the cavity forming substrate 65 having a plurality of the partitions, the nozzle plate 63, and the diaphragm 73. In this case, the cavities 69 are arranged in two parallel rows along a Y direction illustrated in FIG. 8 and forms cavity rows 69A and 69B. In addition, the cavities 69 which are arranged in two parallel rows are arranged in a zigzag manner and the cavities 69 are disposed to be in rows staggered by half a pitch when seen in planar view. Thus, the piezoelectric elements 81 which are provided to correspond to the cavities 69 one-by-one are also arranged in a zigzag manner and inter-positions of the piezoelectric elements 81 in the rows are shifted by a half pitch.

A stainless plate, a single crystal silicon substrate, or the like is preferably applied as material of the nozzle plate 63. In recent years, a high-density and high-definition pattern drawing capability has been required of the liquid discharge head 60, and thus it is necessary to densely arrange a plurality of the nozzles 62 (the through-holes 30) having minute diameters. Therefore, a single crystal silicon substrate on which the through-hole 30 having a minute diameter can be formed is applied. The nozzles through which droplets are discharged are formed, corresponding to the respective cavities 69, on the nozzle plate 63. These nozzles 62 are arranged in two rows along a length direction of a long side of the rectangular-shaped nozzle plate 63. Furthermore, the nozzles 62 are arranged, corresponding to the respective cavities 69, in a zigzag manner. Inter-positions of the nozzles 62 in the rows are shifted by a half pitch. In addition, one row is constituted to have about 360 nozzles 62, for example. Thus, the number of the nozzles 62 constituting two rows is about 720 in total.

A single crystal silicon substrate is preferably applied as material of a reservoir forming substrate 75, and the single crystal silicon substrate is processed by the combination of the through-hole forming methods described above and an anisotropic etching method. The reservoir forming substrate 75 is configured to have a reservoir portion 78 extending in a Y direction and a communication portion 79 for allowing the cavities 69 to communicate with each other. The reservoir 76 has a function of temporarily holding the functional liquid, which is introduced through a functional liquid inlet 77 and supplied to the cavity 69. In other words, the reservoir 76 functions as a common functional liquid holding chamber (an ink chamber) of a plurality of the cavities 69. The functional liquid introduced through the functional liquid inlet 77 passes through an introduction passage 72 and flows into the reservoir 76. Then, the functional liquid passes through a supply passage 74 and is supplied to the cavity 69.

The diaphragm 73 disposed between the cavity forming substrate 65 and the reservoir forming substrate 75 includes an elastic film 84 which is provided to cover an upper surface of the cavity forming substrate 65 and a lower electrode film 85 which is provided on the upper surface of the elastic film 84. The elastic film 84 is formed of a silicon-dioxide film of which the thickness is about 1 μm to 2 μm, for example. The lower electrode film 85 is configured by a metal film of which the thickness is about 0.2 μm, for example. In the embodiments described above, the lower electrode film 85 functions as a common electrode of a plurality of the piezoelectric element 81.

The piezoelectric element 81 for displacing the diaphragm 73 is configured to have a piezoelectric film 87 provided on an upper surface of the lower electrode film 85 and an upper electrode film 88 provided on an upper surface of the piezoelectric film 87. The piezoelectric film 87 is about 1 μm in thickness, for example. The upper electrode film 88 is about 0.1 μm in thickness, for example. In addition, the concept of the piezoelectric element 81 may include the lower electrode film 85, in addition to the piezoelectric film and the upper electrode film 88. That is, the lower electrode film 85 functions as both the piezoelectric element 81 and the diaphragm 73.

A plurality of both the piezoelectric films 87 and the upper electrode films 88, that is, the piezoelectric element 81, are provided to respectively correspond to a plurality of both the nozzles 62 and the cavities 69, as described above. In other words, the piezoelectric element is provided to each nozzle 62 (each cavity 69). The piezoelectric elements 81 are arranged in a zigzag manner. Furthermore, the lower electrode film 85 functions as a common electrode of the plurality of the piezoelectric elements 81, and the upper electrode film 88 functions as an individual electrode of a plurality of the piezoelectric elements 81, as described above. In addition, one end side of the upper electrode film 88 forms wiring electrically connected with a driving circuit (not illustrated).

A compliance substrate 80 which has a sealing film 66 and a fixing plate 67 adheres to the reservoir forming substrate 75. The sealing film 66 is formed of a material (a polyphenylene sulfide film having about 6 μm in thickness, for example) which is low in hardness and has flexibility. The upper portion of the reservoir portion 78 is sealed by this sealing film 66. In addition, the fixing plate 67 is formed of a hard material such as metal (a stainless steel having about 30 μm in thickness, for example). A part of the fixing plate 67 which corresponds to the reservoir 76 is an opening portion 82 in which a part in a thickness direction is completely removed. Thus, the upper portion of the reservoir 76 is sealed by only the sealing film 66 having flexibility and forms a flexible portion 83 deformable by a change in internal pressure.

Usually, in a state where the functional liquid is supplied from the functional liquid inlet 77 to the reservoir 76, the functional liquid flow, which occurs owing to the driving of the piezoelectric element 81, or a pressure change, which is generated in the reservoir 76 by the ambient heat or the like, is caused. However, as described above, the upper portion of the reservoir 76 is sealed by only the sealing film 66 and forms the flexible portion 83, and thus the pressure change is absorbed by a flexural deformation of the flexible portion 83. Accordingly, the pressure in the reservoir 76 is normally maintained constantly.

In addition, the functional liquid inlet 77 through which the functional liquid is supplied to the reservoir 76 is formed in the upper portion of the compliance substrate 80 which is located on an external side of the reservoir 76. The introduction passage 72 by which the functional liquid inlet 77 communicates with a side wall of the reservoir 76 is provided in the reservoir forming substrate 75.

A wiring row portion 90 having a groove shape extending in the Y direction is formed in the central portion of the reservoir forming substrate 75 in an X direction, that is, a portion between two cavity rows 69A and 69B. A part of the cavity forming substrate 65 is exposed through the wiring row portion 90. Below a part of the reservoir forming substrate 75, which is opposite the piezoelectric element 81, a piezoelectric element holding portion 89 which can seal the part of the reservoir forming substrate 75 while holding a space sufficiently large to prevent the inhibition of the movement of the piezoelectric element 81 is provided. The size of the piezoelectric element holding portion 89 is sufficiently large to cover the piezoelectric element 81.

In the liquid discharge head 60 having the configuration described above, the functional liquid is supplied from a functional liquid supply portion (not illustrated) through the functional liquid inlet 77. The functional liquid introduced through the functional liquid inlet 77 passes through the introduction passage 72 and the communication portion 79 and flows into the reservoir 76. The reservoir 76 functions as a common functional liquid holding chamber (an ink chamber) of the plurality of the cavities 69. The functional liquid passes thorough the reservoir 76 and the supply passage 74 and is supplied to the cavity 69.

When a functional liquid discharge command is issued to the liquid discharge head 60 by a controller (not shown), an electric signal is transmitted from the driving circuit, via the wiring row portion 90, to the piezoelectric element 81 of the cavity 69 corresponding to the target nozzle 62. When the piezoelectric element 81 is displaced, and thus the displacement is amplified by the diaphragm 73, the volume of the cavity 69 filled with the functional liquid contracts. As a result, the functional liquid is discharged through the nozzles 62 as droplets. It is possible to print a desired image on a surface of a discharge target object by relatively moving both the liquid discharge head 60 and the discharge target object and selectively discharging droplets.

In the channel forming substrate 70 including the nozzle plate 63, the cavity forming substrate 65, the reservoir forming substrate 75, or the like, the through-hole 30 which is applied to the liquid discharge head 60 and formed by the methods according to the embodiments described above is used as a channel through which the functional liquid flows. In the forming method of the through-hole 30 according to the embodiments described above, it is possible to suppress the thermal reforming from progressing around the portion irradiated with the laser beam L, even when the substrate 10 is thick. Furthermore, it is possible to densely arrange the through-holes 30 having minute diameters. In other words, it is possible to form channels having minute diameters and densely arrange the channels. Therefore, it is possible to densely arrange the channels, corresponding to a plurality of the nozzles arranged densely. As a result, the liquid discharge head 60 can achieve high-density and high-definition drawing.

Hereinbefore, the embodiments of the invention are described. However, various modifications can be applied to the embodiments insofar as they are within the scope of the invention. The flow chart for illustrating the processing processes of the through-hole 30 forming is an example and the invention is not limited thereto. An order change, a replacement or an omission can also be applied to the processes. Furthermore, in the description, the element embedded substrate 40 and the channel forming substrate 70 are exemplified as application examples of the through-hole 30 processed by following the embodiments described above. However, the application example is not limited thereto. The invention can be applied to a structure, such as a thin-film cantilever or a temperature sensor, using the silicon substrate 10 on which the through-hole 30 is formed.

The entire disclosure of Japanese Patent Application No. 2013-21119, filed Feb. 6, 2013 is expressly incorporated by reference herein.

What is claimed is:

1. A silicon substrate processing method comprising:
forming an etching mask which has an opening portion, on a surface of a silicon substrate;
forming an etching guide hole in the opening portion on the silicon substrate; and
forming a through-hole which passes through the silicon substrate, by applying an etching treatment onto the silicon substrate in which the etching guide hole is formed,
wherein, in the forming of the etching guide hole, the etching guide hole passing through the silicon substrate is formed by irradiating the opening portion with a laser beam a plurality of times, with a cooling period between each instance of irradiation with the laser beam.

2. The silicon substrate processing method according to claim 1,
wherein, in the forming of the guide hole, irradiation energy of the laser beam which is applied after one of the cooling periods is greater than the irradiation energy of the laser beam which is applied before the cooling period.
